(19) United States
(12) Patent Application Publication
(10) Pub. No.: US 2012/0000774 A1
(43) Pub. Date: Jan. 5, 2012

(54) Plasma Processing Apparatus

(76) Inventors: Ken YOSHIOKA, Hikari (JP); Yutaka OMOTO, Hikari (JP); Mamoru YAKUSHIJI, Shunan (JP); Tsunehiko TSUBONE, Hikari (JP); Kazunori NAKAMOTO, Kudamatsu (JP)

(21) Appl. No.: 13/230,214

(22) Filed: Sep. 12, 2011

Related U.S. Application Data
(63) Continuation of application No. 11/680,118, filed on Feb. 28, 2007.

(30) Foreign Application Priority Data
Jan. 17, 2007 (JP) 2007-008241

(51) Int. Cl. C23C 14/34

(52) U.S. Cl. 204/298.08; 204/298.09

(57) ABSTRACT

A plasma processing apparatus includes a processing chamber to be depressurized and exhausted, a sample placement electrode provided in the processing chamber and having a sample placement surface on which a substrate to be processed is placed, an electromagnetic generation device to generate plasma in the processing chamber, a supply system that supplies processing gas to the processing chamber, a vacuum exhaust system that exhausts inside the processing chamber, a heater layer and a base temperature monitor that are disposed on the sample placement electrode, a wafer temperature estimating unit that estimates a wafer temperature from the base temperature monitor and plasma forming power supply, and a controller that regulates the heater corresponding to output from the temperature estimating unit.

### CROSS REFERENCE TO RELATED APPLICATION

This application is a continuation of U.S. application Ser. No. 11/680,118, filed Feb. 28, 2007, the contents of which are incorporated herein by reference.

### CLAIM OF PRIORITY

The present application claims priority from Japanese application JP 2007-8241 filed on Jan. 17, 2007, the content of which is hereby incorporated by reference into this application.

### FIELD OF THE INVENTION

The present invention relates to plasma processing apparatuses, such as a plasma etching apparatus provided with a sample stage suitably used to process a substrate-shaped sample, which is a processing target, or a plasma CVD apparatus suited to performing ion implantation or sputtering.

### BACKGROUND OF THE INVENTION

In plasma processing apparatuses, such as etching apparatuses and CVD apparatuses, etching has been conducted by supplying micro waves or an electric field in a high frequency range into a vacuum container; forming plasma in a processing chamber inside the vacuum container in whose lower part an electrode that is a sample stage on which a sample to be processed, such as a semiconductor wafer, is to be placed is previously disposed; and applying a high frequency bias to the sample from the sample stage. Disposed on a surface of the sample stage in plasma processing apparatuses thus composed is an electrode for chucking (holding) the sample using static electricity.

When processing the sample as described above, the temperature of the sample surface is controlled by controlling the average temperature of the entire sample stage surface or by distributing the (in-plane) temperature of the sample stage surface in a radius direction of the sample or sample stage in order to control uniformity of etching or a processed shape of the sample surface obtained by etching. In particular, as miniaturization and complication of semiconductor devices proceed in recent years, plasma processing apparatuses are required to form a further miniaturized processed shape with more accuracy as well as to process a stacked multilayer composed of plural types of films with minute thicknesses.

Plasma processing apparatuses are also required to reduce the time taken by such processing, to increase the number of samples to be processed in a unit time period, that is, the throughput, and thus to etch multilayer films by one operation. The multilayer films here have a film structure in which different types of materials, such as a resist mask, an antireflection film, a carbon film, a metal film (Ti, W, Ta, Mo), a poly-Si film, and an oxide insulating film (high-k materials such as SiO₂ and HfO₂), are laminated. Such a trend can be seen in both front-end-of-line (FEOL) processes and back-end-of-line (BEOL) processes of the semiconductor manufacturing process.

When etching such multilayer films continuously, performing processing, such as etching, on all of multiplayer films made of different materials as described above or on a small group of multilayer portions in one processing apparatus is advantageous in that the time required to process the films or portions is reduced, compared with a method in which, the films made of different materials are processed once, taken out of the processing chamber, and then placed again in the processing chamber to be processed under different conditions.

On the other hand, when performing processing, such as etching, as described above, it is required to perform, for example, etching while maintaining etching uniformity in a wafer surface of each film to be processed in a good condition as well as maintaining the etched shape (perpendicularity, accuracy of dimension relative to etching mask, etc.) in a good condition. In this case, since each film has a preferable wafer temperature and a preferable temperature distribution in a radius direction that depend on the film types, it is desirable that the wafer temperature be changed at a high speed and with high accuracy each time the type of film is changed to anther.

A related art example in which a sample is processed while setting up conditions of the temperature of the sample stage during processing as mentioned above is described in Japanese Patent Laid Open No. 2006-235205.

As a technology that controls the temperature of the sample stage during processing, temperature controllers, as described in the related art example above, are known that include a chiller for controlling the temperature of a sample stage variably by controlling the flow rate of a coolant supplied to a coolant channel disposed inside the sample stage and through which the coolant flows, depending on an output from a temperature monitor for detecting the temperature of the sample stage on whose upper surface a sample is placed. It is also known that, in order to distribute the temperature on the sample using a chiller, coolants with different temperatures are supplied into different coolant channels inside a sample stage.

A technology in which, in order to increase heat transfer between a sample stage surface and a sample, a heat transfer gas is supplied at different pressures through plural routes, and a technology in which a film-shaped heater is embedded in a thin dielectric material on a sample stage so as to apply heat to a sample to a desired temperature are also known.

However, for the temperature controller using a chiller described above, it is not possible to change the distribution of the electrode temperature at a high speed. For the abovementioned technology in which the pressure of He gas is controlled, it is difficult to make a sufficient difference in temperature in a radius direction when heat input from plasma is small as in poly Si etching apparatuses for processing.

For the technology described above in which a heater is embedded, it is possible to avoid problems caused by poor responsiveness to some extent; however, since the film-shaped heater has a high sensitivity, it is not possible to make the temperature (distribution) of the sample surface follow a desired value if the heater is only energized. Therefore, it is required to control the operation of a power supply that supplies power to the heater using a detection result of the temperature of the sample. However, it is difficult to detect the temperature of the sample itself practically at an industrial level and thus to control the temperature of the sample.

As methods for directly detecting the temperature of a sample, there are a technology in which a temperature monitor, such as a contact type thermocouple thermometer, a fluorescence thermometer, or an infrared thermometer, is provided in a lower part of a sample stage and a technology in which the temperature of a sample is detected using radiation from outside a plasma processing chamber above a sample stage. However, these related art technologies are difficult to achieve high reliability that endures mass-production, due to their low cost performance, low reliability in long term use, and the like.

Thus, instead of directly monitoring the temperature of a sample, there has been used a technology, as described in the above Japanese Patent Laid Open No. 2006-235205, in which a thermocouple, a platinum resistor, or the like embedded in a member included in a sample stage, such as a base member, is used as a sensor; a temperature is detected based on an output from such a sensor; and the operation of a power supply for a heater is controlled using the detected temperature. Such a monitoring technology using a thermocouple or a platinum resistor has sufficient industrial reliability. However, there is generally a discrepancy of 5 to 25° C. between the temperature of the base member and that of the actual sample. The discrepancy varies with conditions of the operation of a plasma processing apparatus that performs etching or the like, and also varies with time due to long-term use of the apparatus. Therefore, the above described related art is not enough to carry out sufficient temperature control to perform fine etching.

### SUMMARY OF THE INVENTION

The present invention provides a plasma processing apparatus that controls the temperature of a sample at a higher speed and with more accuracy to improve the efficiency of processing the sample.

The present invention is intended to overcome the aforementioned problems through means for measuring and estimating a distribution of a wafer temperature based on a signal from a base temperature monitor embedded in a base member of a sample stage and means for performing feedback control on a heater power supply based on the estimated temperature distribution.

One example of typical aspects of the present invention is as follows. A plasma processing apparatus according to an aspect of the present invention includes a processing chamber to be depressurized and exhausted, a sample stage provided in the processing chamber and having a sample placement surface on which a substrate to be processed is placed, a plasma generation device to generate plasma in the processing chamber, a heat transfer gas supply system that supplies heat transfer gas to the sample placement surface, a portion defining a coolant channel provided inside the sample stage and through which a coolant circulates, a heater layer provided between the sample placement surface and the portion defining a coolant channel inside the sample stage, the heater layer being formed so as to be divided into a plurality of regions in a radius direction of the sample placement surface, a temperature monitor provided near the heater layer in the sample stage and in a position corresponding to each of the division regions of the heater layer, and a temperature controller that estimates a temperature of a position corresponding to each of the division regions of the substrate placed on the sample placement surface base on temperature data from the temperature monitor and controls power supply to each of the division regions of the heater layer according to the estimated temperature value.

According to the present invention, it is possible to provide a plasma processing apparatus that controls the temperature of a sample at a higher speed and with more accuracy to improve the efficiency of processing the sample.

### BRIEF DESCRIPTION OF THE DRAWINGS

An embodiment of the present invention will be described in detail based on the following drawings, wherein:

FIG. 1 is a sectional view showing a sample placement electrode according to the embodiment of the present invention;

FIG. 2A is a drawing showing composition of a control system of the electrode according to the embodiment of the present invention;

FIG. 2B is a longitudinal sectional view schematically showing composition of a sample stage according to the embodiment;

FIG. 2C is a longitudinal sectional view schematically showing a modification of the composition of is the sample stage according to the embodiment;

FIG. 3 is a drawing showing an algorithm in a wafer temperature estimating unit of the electrode according to the embodiment of the present invention;

FIG. 4 is a block diagram showing real-time computation in the wafer temperature estimating unit of the electrode according to the embodiment of the present invention;

FIG. 5 is a block diagram showing a control computing unit including a PID control system according to the embodiment of the present invention;

FIGS. 6A to 6C are graphs showing an advantageous effect of wafer temperature control by the electrode according to the embodiment of the present invention;

FIGS. 7A to 7C are graphs showing an analysis example (1) of behavior of a wafer temperature of an electrode according to a related art example;

FIGS. 8A to 8D are graphs showing an example of fine-tuning of a wafer temperature profile by the electrode according to the embodiment of the present invention;

FIGS. 9A and 9B are graphs showing an example of restraint of transient changes in wafer temperature at the time of plasma ignition of the electrode according to the embodiment of the present invention; and

FIGS. 9C and 9D are graphs showing transient changes in wafer temperature at the time of plasma ignition of the plasma etching apparatus according to the related art example, as a comparative example; and

FIGS. 10A to 10D are graphs showing an example of restraint of temporal changes in wafer temperature at the time of change of a coolant temperature of the electrode according to the embodiment of the present invention.

### DETAILED DESCRIPTION OF THE PREFERRED EMBODIMENTS

An embodiment to the invention will now be described with reference to the accompanying drawings.

### Embodiment

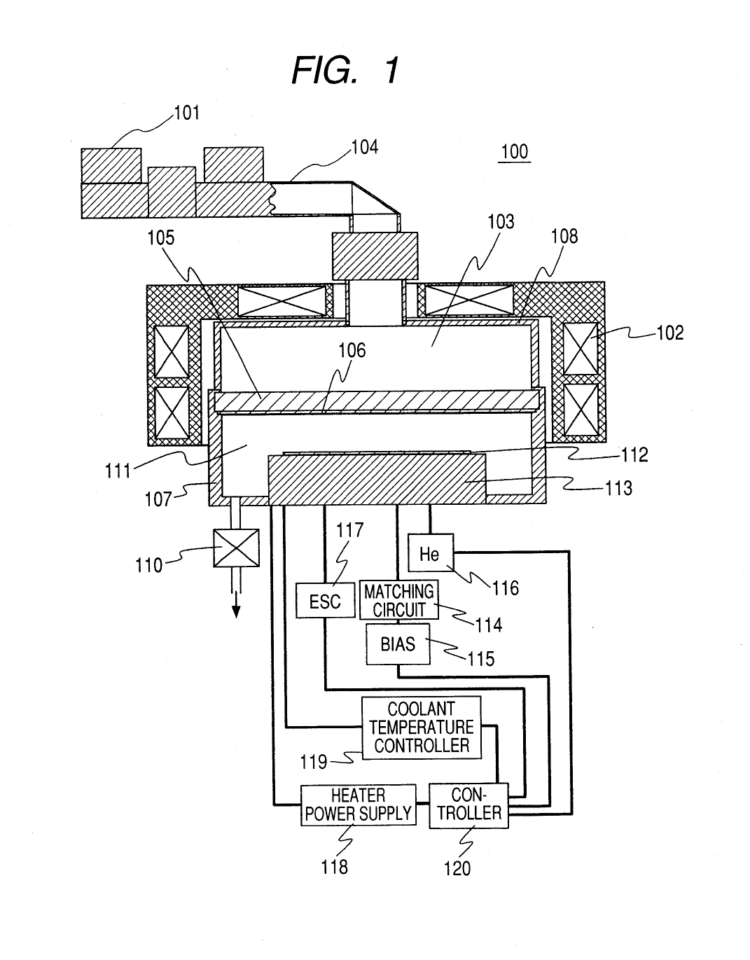

The embodiment according to the invention will be described referring to FIGS. 1 to 4.

FIG. 1 is a longitudinal sectional view schematically showing composition of a plasma etching apparatus according to this embodiment. As shown in FIG. 1, a plasma etching apparatus includes an approximately cylindrical processing chamber 111 disposed in a vacuum container 107 and depressurized, and a microwave source 101, formed of a magnetron, and a waveguide 104 that are both disposed above the processing chamber 111. The lower end of the waveguide 104 is coupled to a resonation container 108 disposed in an upper part of the vacuum container 107 so that the inside of the waveguide 104 and the resonation chamber 103 inside the resonation container 108 communicate with each other. Microwaves propagated from the microwave source 101 through the waveguide 104 are introduced into the resonation chamber 103 and resonated in a predetermined mode. Disposed between the resonation chamber 103 and the processing chamber 111 is a window member 105 that is provided to partition these chambers and includes an approximately circular plate made of a dielectric material such as quarts. Disposed on a surface of the window member 105 adjacent to the processing chamber 107 is a shower plate 106 that is made of a dielectric material and has plural gas introduction holes (not shown) through which processing gas is supplied into the processing chamber. The shower plate 106 constitutes a ceiling surface of the processing chamber 111. A processing gas supplying route (not shown) through which processing gas is introduced is connected to space between the shower plate 106 and window member 105.

Disposed inside the processing chamber 111 is a sample stage (a sample placement electrode) 113 on which a substrate (wafer) 112 to be processed is placed.

In this composition, microwaves from the microwave source 101 resonated inside the resonation chamber 103 are transmitted through the window member 105 and shower plate 106, which both constitute the bottom of the resonation chamber 103, and then supplied into the processing chamber 107. Supplying microwaves from the microwave source 101 into the processing chamber 111 in this manner and exciting processing gas introduced into the processing chamber 111 into plasma, the substrate (wafer) 112 is processed using the plasma.

The sample stage 113 on whose upper surface a sample to be placed is disposed in a lower center section inside the processing chamber 111. As discussed later, the sample 112 is made to have a predetermined electrical potential and maintained at a predetermined temperature during processing. A bias power supply 115 is coupled to the sample stage 113 via an automatic matching circuit 114. Heat transfer gas is supplied to a gap between the surface of the sample stage 113 and the back surface of the sample placed on the sample stage from a heat transfer gas (He) supply system 116.

Designated by reference numeral 117 a direct current power supply for electrostatic absorption, 118 a heater power supply, 119 a temperature controller for circulating and supplying a coolant, and 120 a temperature controller. These members will be described in detail below.

When the sample is processed, processing gas is supplied from the gas introduction holes of the shower plate 106 disposed so as to face the upper surface of the sample stage 113, while an electric field of microwaves is supplied from the window member 105 and a magnetic field is supplied from a solenoid coil 102 disposed around the side of the vacuum container 107 or resonation container 108 or around the upper part of those members. By mutual operation among the processing gas, electric field, and magnetic field, the processing gas is excited into plasma, thereby subjecting the sample 112 to plasma processing. To generate plasma, it is possible to use plasma generating means using inductive coupling or electrostatic coupling using a high frequency instead of microwaves.

Disposed below the vacuum container 107 is a vacuum exhaust system 110, such as a vacuum pump, for exhausting and depressurizing the processing chamber 111. Thus, it is possible to exhaust particles, such as gas, plasma, and products generated through the processing, from a lower part of the processing chamber 111 while supplying processing gas from an upper part of the processing chamber 111 to generate a plasma, thereby maintaining the inside of the processing chamber 111 in an atmosphere and a pressure suitable for the processing.

The sample 112 is subjected to bias power supplied from the bias power supply 115 via the automatic matching circuit 114 disposed below the sample stage 113 with the sample 112 placed on the sample placement surface. Thus, the sample 112 is given a predetermined potential during processing, and ions in the plasma are draw onto the surface of the sample 112 so that the sample is etched into a desired shape.

Heat transfer gas, such as He, for promoting heat transfer between the sample 112 and the surface of the sample stage 113 is introduced into the sample stage 113. Disposed below the sample stage 113 is the gas supply system 116 for supplying heat transfer gas such as He. The introduction route through such heat transfer gas is supplied is provided below and inside the sample stage 113. In an upper part of the sample stage 113, an electrostatic electrode that absorbs the sample by electrostatic force so as to hold the sample 112 on the sample placement surface of the sample stage 113 even if the heat transfer gas is supplied during processing, and a heater electrode that heats the sample 112 to a predetermined temperature are also disposed. The direct current power supply 117 and heater power supply 118 for supplying power to these electrodes, respectively, are disposed below the sample stage 113.

In order to make the temperature of the sample 112 a desired one suitable for processing, this embodiment is provided with a temperature controller 119 that circulates and supplies a coolant to a route provided in the sample stage 113. A coolant temperature-controlled by this temperature controller 119 is supplied to a coolant channel 122 inside the sample stage 113 via a route connected to the sample stage 113. On the other hand, a coolant whose temperature has increased by heat exchange is exhausted from the coolant channel 122 and returned to the temperature controller 119, and then temperature-controlled again to be supplied to the sample stage 113 for circulation.

A temperature monitor for detecting a temperature and outputting a detection signal is disposed in plural positions inside the sample stage 113 provided with plural controllers for controlling the temperature of the sample stage 113 or sample 112 as described above. There is provided the temperature controller 120 for controlling the output of the heater power supply 118, the pressure of He gas from the gas source 116 for heat transfer, the outputs of the bias power supply 115 and direct current power supply 117 upon receipt of an output from this temperature monitor.

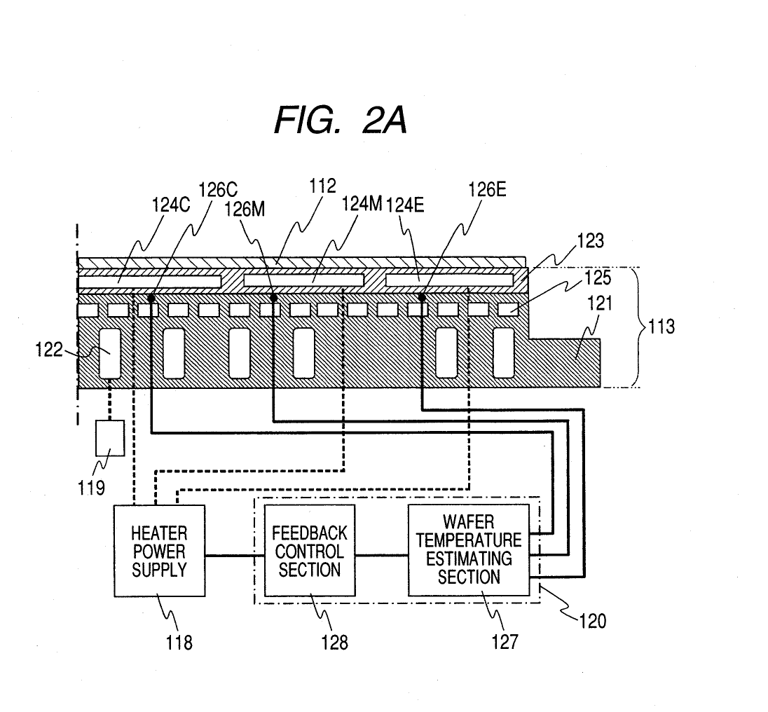

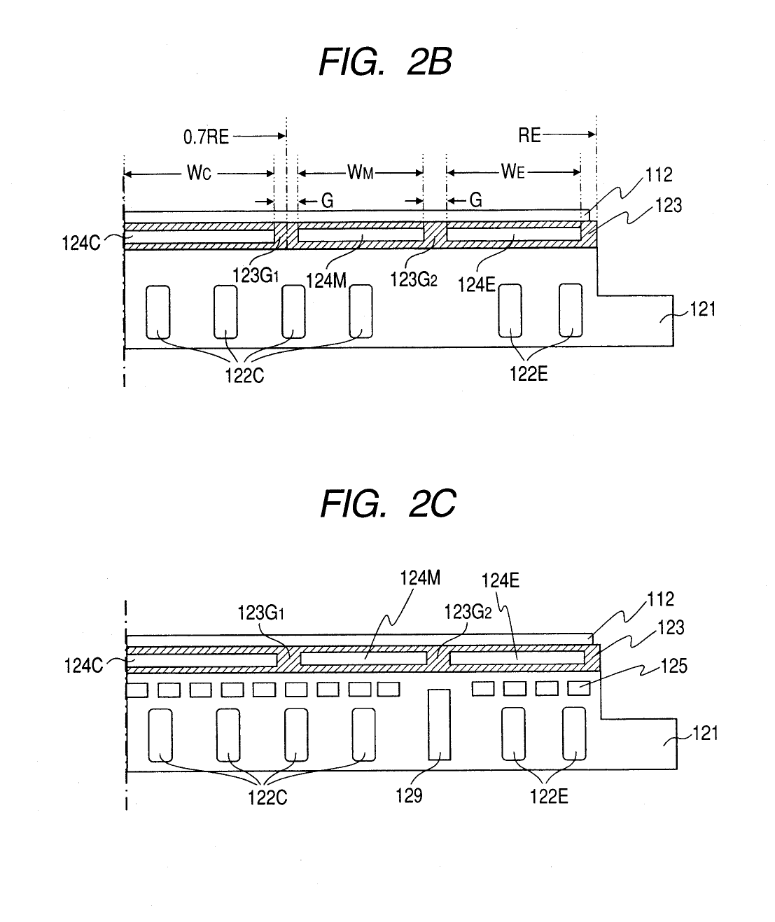

Referring now to FIGS. 2A to 2C, the composition of the inside of the sample stage 113 and the temperature controller 120 will be described.

FIG. 2A is a longitudinal sectional view schematically showing the composition of the sample stage 113 and temperature controller 120. FIGS. 2B and 2C are longitudinal sectional views schematically showing the composition of the sample stage 113.

As shown in FIG. 2A, the sample stage 113, whose upper part is approximately cylindrical, includes the base member 121 formed of a metal such as Al or Ti and the dielectric material film 123 formed of a dielectric material such as Al₂O₃. Formed inside the base member 121 is the coolant channel 122 that is a passage through which a coolant for temperature-controlling (cooling) the base member 121 flows. The coolant channel 122 is a route for a heat exchange medium, such as water or Fluorinert (a trademark), disposed concentrically or spirally with respect to the center of the base member 121 taking the shape of an approximate disc. A coolant is supplied from the inlet (not shown) of the coolant channel 122 adjacent to the periphery of the base member 121 and exhausted from the outlet (not shown) of the coolant channel 122 adjacent to the center of the base member 121. The temperature of a coolant is controlled so as to be maintained at a given value lower than the minimum value of the control target temperature of the sample 112.

The dielectric material film 123, which is made of a dielectric material such as Al₂O₃, is formed, for example, by thermal spraying. Disposed inside the dielectric material film 123 is the heater electrode film (heater layer) 124, and the upper and lower parts of the heater electrode film 124 are covered with the dielectric material film 123.

As a metal to be subjected to thermal spraying to form the heater electrode film 124, a metal whose resistivity is controlled, such as W, nickel chrome alloy or nickel aluminum alloy whose resistivity is controlled, or a metal in which W is mixed with an appropriate additive metal to control the resistivity, is used. The dielectric material film 123 may be sintered ceramics that has a metal film for the electrode film 124 embedded therein and is made of Al₂O₃, AlN, or Y₂O₃.

The electrode film 124 according to this embodiment is disposed separately in three regions, that is, a central region of the sample stage 113 (base 121 member plus dielectric material film 123) in the form of a disc, an edge region of the sample stage 113 in the form of a ring concentric with the disc, and a middle region located between these two regions. In other words, the heater electrode film (heater layer) 124 according to this embodiment includes plural parts provided concentrically, that is, three regions: a central part 124C, a middle part 124M, and an edge part 124E. Those parts as a whole are provided in a region approximately corresponding to the entire surface of the dielectric material film 123 or sample 112, or a region containing the entire surface of the sample 112. The heater layers disposed in the three regions are constructed so as to have approximately equal areas. The method for designing the heater electrode film 124 will be discussed later. Though not shown inside the dielectric material film 123, a metal thin film layer of the electrostatic electrode for absorbing the sample 112 may be embedded and disposed above the electrode film 124.

As shown in FIG. 2B, the three regions of the electrode film (heater layer) 124, that is, the central part 124C, middle part 124M, and edge part 124E have widths in a radius direction, W_{C}, W_{M}, and W_{E}, respectively. The three parts are separated and electrically insulated from each other by partition walls 123G1 and 123G2 that each include a part of the dielectric material film 123 and have a width G in a radius direction. The widths G (may not be equal) of the partition walls 123G1 and 123G2 are sufficiently smaller than the widths of the regions of the electrode film, W_{C}, W_{M}, and W_{E}.

The partition wall 123G1 between the central part 124C and the middle part 124M of the heater electrode film 124 is disposed in a position corresponding to approximately 0.7 times a radius R_{E} from the center to the edge of the dielectric material film 123, or a radius of the base member 121 or sample stage 113, or in a position inner than the abovementioned position.

The electrode film 124 is constructed so that as the temperature gradient in a radius direction of the sample 112, the temperature gradient between the central part 124C and middle part 124M is basically smaller than that between the middle part 124M and edge part 124E.

The coolant channel 122 according to this embodiment includes plural coolant channels 122C adjacent to the center of the base member 121 and plural coolant channels 122E adjacent to the edge of the base member 121. Heat transfer media having different temperatures are circulated through the coolant channels 122C and coolant channels 122E. Specifically the temperature of a coolant is controlled so as to become lower in the coolant channel 122E adjacent to the edge and to become higher in the coolant channel 122C adjacent to the center. The partition wall 123G1, which separates the central part 124C and middle part 124M of the electrode film (heater layer) 124, is disposed corresponding to the coolant channels 122C above a central part of the base member 121 where the coolant channels 122C adjacent to the center are disposed. Moreover, in this embodiment, the coolant channels 122E adjacent to the edge are located outside the partition wall 123G2 of the electrode film (heater layer) 124. In other words, the coolant channels 122E adjacent to the edge are disposed below the electrode film (heater layer) 124E adjacent to the edge and in positions that overlap the electrode film (heater layer) 124E.

As shown in FIG. 2C, a ring-shaped slit 129 in which evacuated or filled with gas for restraining heat transfer in a radius direction of the sample stage 113 may be provided below the electrode (heater layer) 124 inside the sample stage 113. In this case, the slit 129 is positioned at least outside a position corresponding to the partition wall 123G1 in a radius direction, or may be disposed below the partition wall 123G2 that separates the central part 124C and edge part 124E.

As shown back in FIG. 2A, a temperature insulating layer 125 in which evacuated or filled with gas for increasing the speed at which the temperature of the sample 112 is controlled is disposed to extend across the lower surface of the dielectric material layer 123 between the coolant channel 122 and dielectric material layer 123 located on the base member 121. Note that even if this temperature insulating layer 125 is not provided, temperature control according to this embodiment to be discussed below can be carried out.

In this embodiment, the temperature monitor 126 made of a thermocouple or a platinum resistor is disposed in parts of the base member 121 above the temperature insulating layer 125 inside the base member 121. The temperature monitor 126 includes three temperature monitors 126 (C, M, E), which are provided near the center of the center, middle, and edge parts, respectively, of the heater. The temperature monitors 126 are provided in order to properly control operation instructions of the temperature controllers for a coolant in the coolant channel 122, the electrode film 124, the pressure of He described above, and the like. The temperature monitors 126 correspond to the three parts of the heater layer and are disposed approximately in the respective centers of those heater layer parts.

Signals outputted from these three temperature monitors 126 (C, M, E) are transmitted to a wafer temperature estimating unit 127 in the temperature controller 120 outside the sample stage 113. The operation of the wafer temperature estimating unit 127 will be described later. The temperature controller 120 also includes a control computing unit 128 coupled to the wafer temperature estimating unit 127. The control computing unit 128 computes and detects the temperatures of the parts (C, M, E) of the sample 112 corresponding to the parts (C, M, E) of the electrode film 124, compares the temperatures of these parts (C, M, E) of the sample 112 with the corresponding target values, and computes operation instructions to the temperature controllers for the sample stage 113 using the comparison results. For example, the control computing unit 128 outputs an instruction for making the power output from the heater power supply 118 a predetermined value.

With regard to computations carried out by the control computing unit 128, it is found out in studies by the inventors and the like that since the time constants for the temperature controllers for the sample stage 113 are large and the temperature controllers are stable, it is possible to control the temperature of the sample stage 113 or sample 112 with sufficient accuracy by ON/OFF of each temperature controller corresponding to a signal concerning the difference between the estimated and target temperatures of the sample 112 or by a control computation made by the PID control system or the like where a large gain is ensured. The heater power supply 118 controlled in this embodiment supplies power to the electrode films 124 (C, M, E) based on an instruction from the temperature controller 120.

### [Temperature Estimating Unit]

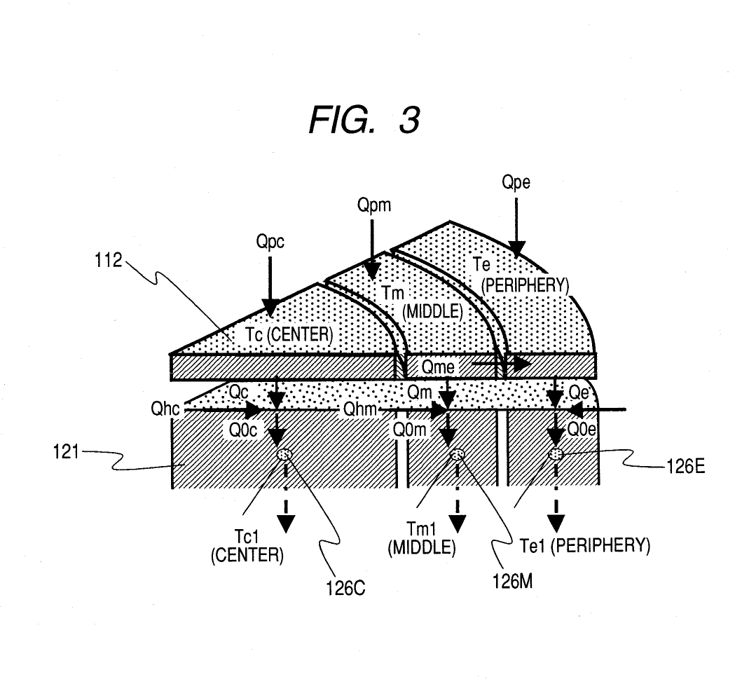

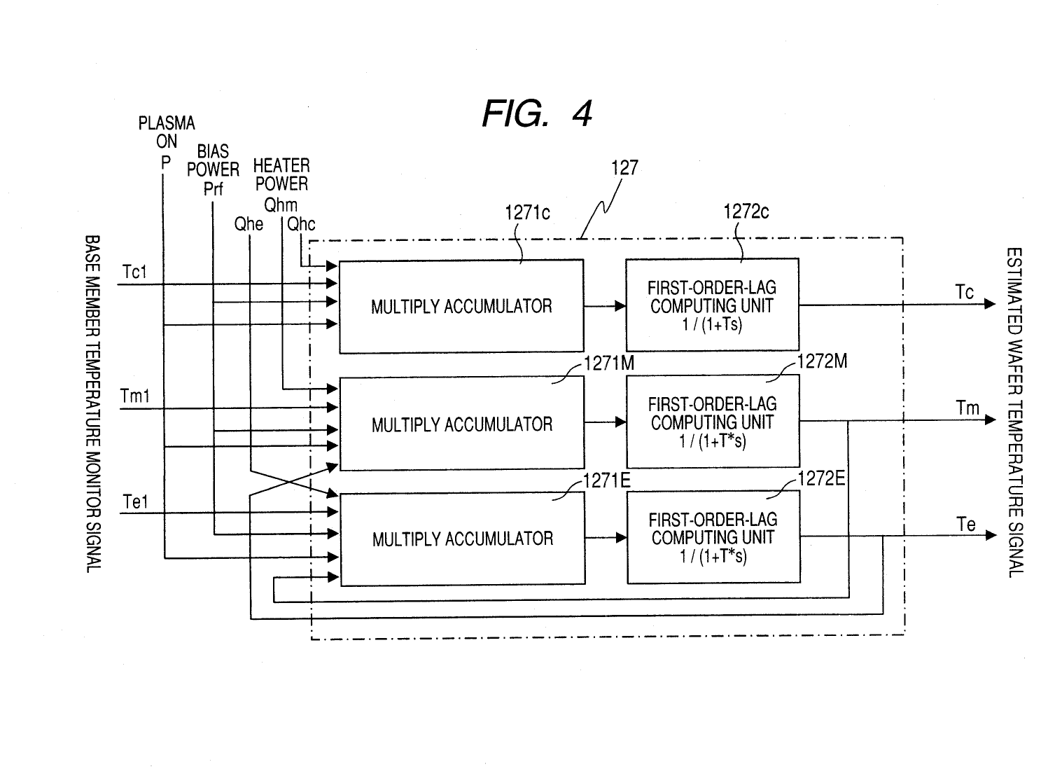

Referring now to FIGS. 3 and 4, the composition and operation of the wafer temperature estimating unit 127 will be described. FIG. 3 is a conceptual view showing the concept concerning the processing of estimating the temperature of the sample 112 performed by the wafer temperature estimating unit 127. This drawing schematically shows the concept concerning heat transfer between the parts (central, middle, and edge parts) of the sample 112 corresponding to the electrode films 124 disposed below the sample 112 and the corresponding parts (central, middle, and edge parts) of the base member 121 below the sample 112.

In this embodiment, two heat transfer regions, that is, upper and lower regions are considered separately. Specifically, heat balance of the sample 112 itself and heat balance of the base member 121 (a portion of the base member 121 near a base temperature monitor) are considered separately.

First, the regions of the sample 112 are described. The respective heat capacities of the parts (central, middle, and edge parts) obtained by dividing the sample 112 into three equal parts in a radius direction are defined by Ci (i=C/M/E). The heat capacity is represented by Ci=cρV, where c=Si specific capacity, ρ=Si density, and V=(volume of sample 112)/3. The respective temperatures (average temperature in each division block), Te (edge part), Tm (middle part), Tc (central part), of the three equal parts (C, M, E) obtained by dividing the sample 112 are represented by formula 1 below using the balance of heat that enters and leaves each part.

CdTe/dt=A(Te−Te0)+Qpe−Ame(Te−Tm);

CdTm/dt=A(Tm−Te0)+Qpm−Ame(Tm−Te)−Acm(Tm−Tc); and

CdTc/dt=A(Tc−Te0)+Qpe−Acm(Tc−Tm) [formula 1]

where
Te0, Tm0, Tc0: temperature of base member surface (=dielectric material thermal-sprayed film)
Qpe, Qpm, Qpc: heat input from plasma
A=αS: α=He overall heat transfer coefficient (function of He pressure) between wafer and base member surface (dielectric material surface); S is area of ⅓ wafer
Ame, Acm: overall heat transfer coefficient of wafer in horizontal direction

In formula 1, Acm (Tm−Tc) and Acm (Tc−Tm) are negligible.

In this embodiment, it is assumed that heat input from plasma is a specific linear function with respect to power Prf from the bias power supply 115 and strength Pμ of μ wave from the microwave source 101.

Next, heat balance of the base member surface, that is, thermal sprayed film is described.

Heat balance of the base member 121 (a part of the base member 121 near the base temperature monitor 126) is represented by formula 2 below.

C0dTe0/dt=−A(Te−Te0)+Qhe−A0(Te0−Te1);

C0dTm0/dt=−A(Tm−Te0)+Qhm−A0(Tm0−Tm1); and

C0dTc0/dt=−A(Tc−Te0)+Qhe−A0(Tc0−Tc1) [formula 2]

where
heat capacity: C0=cρV
Te0, Tm0, Tc0: temperature of base member surface (=dielectric material thermal-sprayed film)
Te1, Tm1, Tc1: temperature of base temperature monitor
Qhe, Qhm, Qhc: heat input from heater
A0=α0S: α0=overall heat transfer coefficient of the base member

Here, the heat transfer coefficient of He gas is much smaller than that of a metal, thus each of the first terms in the right side of the formula 2 is negligible.

Further, since the time constant of the formula 2 is relatively small enough compared with the time constant of the formula 1, thus each of the terms in the left side of the formula 2 is negligible. For example, the time constant of the formula 1 is; (C/A)=3.8 (s), and the time constant of the formula 2 is; (C0/A0)=0.26 (s).

Thus, formula 3 below holds true from heat balance between the surface of the base member 121 and dielectric material film 123.

Tc0=Tc1+Qhc/A0;

Tm0=Tm1+Qhm/A0; and

Te0=Tc1+Qhe/A0 [formula 3]

When formula 1 is transformed using formula 3, the following formula 4 is obtained.

Te=1/(1+T*s)·[(A/A*)·(Te1+QHe/A0)+Qpe/A*+(Ame/A*)Tm]

Tm=1/(1+T*s)·[(A/A*)·(Te1+Qhm/A0)+Qpm/A*+(Ame/A*)Te]

Tc=1/(1+Ts)·[Tc1+Qhc/A0)+Qpc/A] [formula 4]

where

A*=A+Ame, T*=C/(A+Ame), T=C/(A)

That is, in this embodiment, the temperature of the sample 112 is estimated by a first order lag computation using the detected temperature of the base member 121, the input power to the electrode film 124, and heat input from plasma to the sample as inputs. Here, the relations among heat input from plasma, microwave power, and bias power are theoretically computed or determined based on real machine data as fit parameters in advance.

FIG. 4 shows the abovementioned real-time computing functions of the wafer temperature estimating unit 127 as a block diagram. FIG. 4 is a block diagram showing the flow of estimation made by the wafer temperature estimating unit 127 shown in FIG. 2A. As shown in the diagram, in the temperature estimating unit 127 according to this embodiment, the functions for the temperatures of the central, middle, and edge parts are obtained by a multiply accumulator 1271 (C, M, E) using multiplication and addition based on output signals from the temperature monitors 126 for detecting the temperature of the base member 121 and information on microwave power of plasma, power from the bias power supply 115, and power from the heater power supply 118 to the electrode films 124, which are heaters, and then first order lag computations are made by first order lag computing units 1272 (C, M, E) to estimate the wafer temperature. These computations make it possible to estimate the temperatures (Tc, Tm, Te) with high accuracy while following transient changes in temperature with good responsiveness.

### [Control Computing Unit]

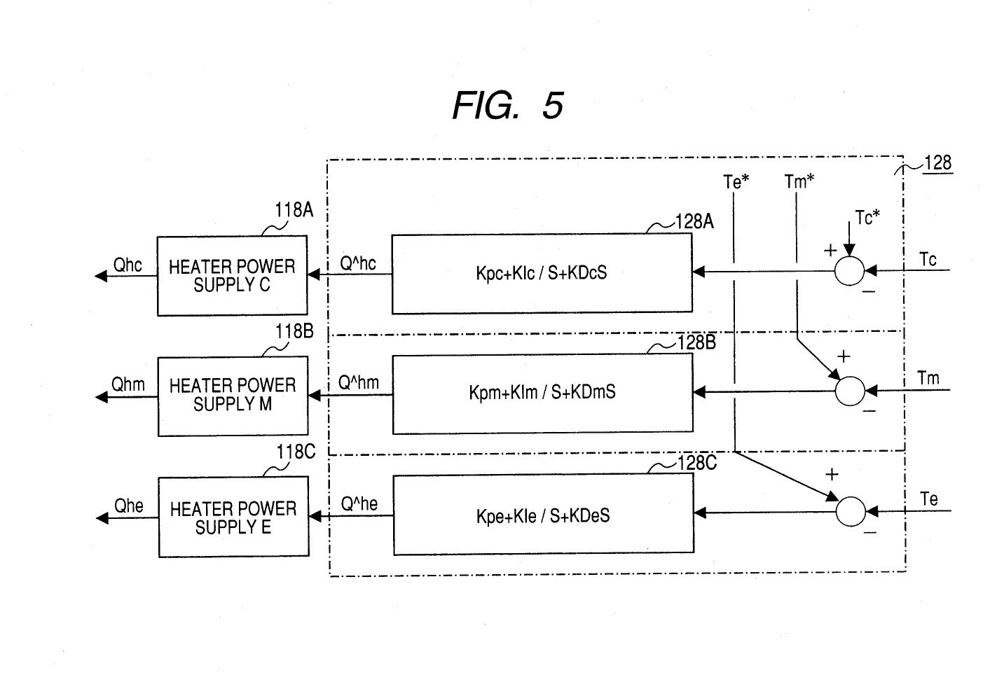

FIG. 5 shows a control computing unit including a PID control system as a specific composition example of the control computing unit 128. The control computing unit 128 performs PID control computations corresponding to signals regarding the differences between the temperatures (Tc, Tm, Te) of the sample estimated by the wafer temperature estimating unit 127 and the target values (Tc*, Tm*, Te*) of the sample temperature, and then outputs the signals to the heater power supply 118 (C, M, E).

### [Temperature Insulating Layer]

Next, the composition of the temperature insulating layer 125 is described. Disposed on an upper part of the base member 121 according to this embodiment are plural dimple-shaped protrusions made of a Ti material. As shown in FIG. 2A, this dimple structure is joined to the main body of the base member 121 by brazing. The height of those dimples structure is, for example, 3 mm.

In such composition, the ratio of the overall area of the dimple structure of the temperature insulating layer 125 to the area of the upper surface of the sample stage 113 is about 25%. It is founded out in studies by the inventors and the like that the overall heat transfer coefficient between the upper and lower portions of the base member 121 with the temperature insulating layer 125 therebetween is about one-fourth of that when such a temperature insulating layer is not provided.

The temperature insulating layer 125 may be formed by other methods. For example, it is possible to provide a vacuum layer with a thickness of about 5 to 500 μm on the approximately entire upper surface of the base member 121 and then to introduce He at a pressure of about 1 to 10 kPa thereto. The brazing pattern is not required to be dimple-shaped and only required to be formed so as to demonstrate limited heat transfer coefficients that are approximately uniform across the surface. For example, the temperature insulating layer 125 may be formed using zirconia ceramics, which has a small heat transfer coefficient, or the like. As described above, the temperature insulating layer 125 may be omitted depending on control characteristics required for the plasma etching apparatus.

### [Electrode Film]

Next, the electrode film 124 is described in detail. The electrode films 124, which serve as heaters, are made of W (tungsten) having a width of 2.5 mm and a thickness of 150 μm and are disposed inside the dielectric material film 123 so as to cover the entire sample placement surface of the sample stage 113 with 4-mm pitches. The three heaters including the central, middle, and edge parts having nearly equal areas receives power via feed terminals.

When seen from above the sample stage 113, each electrode film 124 is divided into blocks in the first to fourth quadrants with the central axis of the sample stage 113 that is circular in cross section as the origin. Those quadrants are connected in series so that there is continuity between those quadrants. While there may occur nonuniformity in temperature of the sample 112 heated in a circumferential direction depending on unevenness in thickness of the W film, this is intended to previously eliminate the cause for nonuniformity in temperature in a circumferential direction by performing additional polishing when manufacturing the electrode film 124.

The feed terminal to each electrode film 124 is disposed so as to avoid a hole for supplying heat transfer gas such as He and a pusher pin hole. The feed terminal is preferably is disposed approximately uniformly across the sample placement surface of the sample stage 113 so as not to make a blank area if possible. In this embodiment, the resistance of the three electrode films 124 when seen from the corresponding feed terminals is about 20Ω. If a power supply with a maximum rating of 1 kW is used in consideration of use of the heater power supply 118 that is general-purpose and low-cost, the current to be passed is about 7 A. This allows a feed cable with a small diameter to be used, making the design compact.

As shown back in FIG. 2A, the design of the coolant channel 122 is similar to that of typical electrodes that have been used. In other words, a chlorofluorocarbon coolant is used. In this embodiment, a heat load of a maximum of 3 kW is instantly applied to the parts of the electrode film 124, so the temperature of the base member 121 around the coolant channel 122 may vary transiently. However, as described in the numeric computations later, the load of a maximum of 3 kw is applied in a limited time period when the temperature of the sample 112 is increased. Moreover, even if the temperature of the part of the base member 121 in which the coolant channel 122 is disposed varies in such a time period to some extent, controlling the temperature of the sample 112 by the electrode film 124 being feedback-controlled prevents the lower part of the base member 121 from having effects on the temperature of the sample 112. Furthermore, in this embodiment, there is provided the temperature insulating layer 125 between the lower part of the base member 121 in which the coolant channel 122 is disposed and the dielectric material layer 123 including the electrode film 124 on the base member 121. This further reduces the effect of the coolant channel 122 on the temperature control of the electrode film 124. Thus, a low cost temperature controller can be used as the temperature controller 119, which serves as a circulator for coolant.

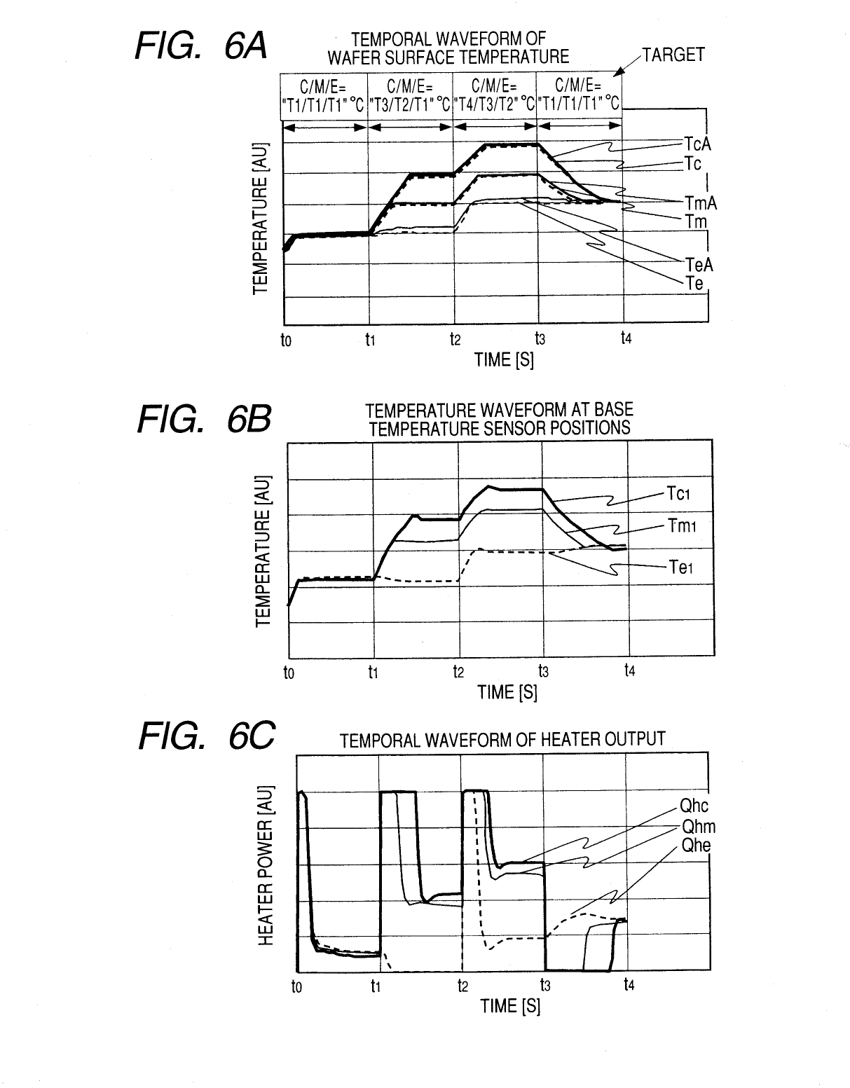

Hereinafter, the advantages of this embodiment described above will be explained referring to FIGS. 6A to 8D. The advantages of this embodiment are confirmed by the numerical computations described below. In these numerical computations, each of the base member 121 (including the coolant channel 122 and the temperature insulating layer 125), the sample 112, the dielectric material layer 123 formed on the base member 121, and the electrode film 124 embedded in the dielectric material film 123 is divided into 150 meshes in a radius direction and 8 meshes in a vertical direction, and an axisymmetric two-dimensional heat transfer equation is used. This numerical analysis technique is verified by experimental data separately. It is found out in studies by the inventors and the like that these numerical computations have a certain level of reliability.

The algorithm for estimating the temperature of the sample 112 and the algorithm for controlling the heater power supply 115 described in the formula 4 and FIG. 4 are added to these numerical computations. This makes it possible to check the response of the temperature of the sample 112 made by the feedback control according to this embodiment. These numerical computations are designed such that start of etching, heat input from plasma, and heat input disturbances to the controllers can be simulated. Unless otherwise specified, gate poly-Si etching of a typical semiconductor device is simulated in these computations and it is assumed that the wafer is subjected to an equal heat input of 160 W when the processing is started by plasma ignition

The conditions required for these computations are the pressure of He to be introduced between the back surface of the sample 112 and the upper surface of the dielectric material layer 123 that is an upper part of the sample stage 113, and the pattern of the grooves on the upper surface of the dielectric material layer 123 disposed so that He extends across the back surface of the sample 112. Unless otherwise specified, the pressure of He is assumed to be 1.5 kPa. The force by which the sample 112 is attracted electrostatically so as to be pushed to the surface of the sample stage 113 is assumed to be about 10 kPa. The initial temperature of the sample 112 is assumed to be the ambient temperature (25° C.).

FIGS. 6A to 6C show a first example of the result. FIGS. 6A to 6C are graphs showing time-lapse changes in temperature of the parts when control is carried out under the following conditions.

(1) Processing using plasma is started at the time point of t0. The wafer temperature target values for C (central part)/M (middle part)/E (edge part) until the time point t1=T1/T1/T1 ° C.
(2) Until time point t2, C/M/E=T3/T2/T1 ° C.
(3) Until time point t3, C/M/E=T4/T3/T2 ° C.
(4) Until time point t4, C/M/E=T1/T1/T1 ° C.

In FIG. 6A, the temperatures (dotted lines) of the sample 112 estimated using formula 4 and the actual temperatures (solid line) are overlapped. The temperature of the coolant is maintained at a value lower than the minimum control target temperature for the sample 112, for example, 5° C. (same in the examples below). In each part, the estimated temperature T (c, m, e) and the actual temperature T_{A} (c, m, e) is matched within 1° C. In this embodiment, when the target values of the sample 112 are changed, the respective temperatures of the central, middle, and edge parts makes changes toward the new target values at a temperature change speed of 1° C./sec. or more.

FIG. 6B is a graph showing time-lapse changes in the temperatures T1 (c, m, e) detected from outputs from the temperature monitors 126 of the base member 121. In this embodiment, when heat from plasma is inputted, there occurs a difference of 10° C. to 30° C. between the temperature of the sample 112 and that of the surface of the base member 121 since the overall heat transfer coefficient of He, which is gas for heat transfer between the sample 112 and the surface of the sample stage 113, is limited.

In order to match the temperatures of the sample 112 shown in FIG. 6A with the target values, a signal regarding the temperature of the sample 112 or sample stage 113 detected from an output from the temperature monitor 126 is fed back, and thereby the operation of the temperature controller such as the electrode film 124 is controlled. As a result, signals from the temperature monitors 126 disposed in the upper part of the base member 121 shape waveforms as shown in FIG. 6B. FIG. 6C shows time-lapse changes in output of power Qh (c, m, e) from the heater power supply. Signals based on outputs from the temperatures sensor 126 are fed back so as to match the temperatures of the sample 112 with the target values, and thereby control is performed. As a result, the electrode films 124, which serve as heaters, are given power and operated so as to have a maximum of calorific value at the time of start (=t0) and at the time of increase of the target temperature (for example, t3). Subsequently, the element film 124 operates so that its output and thus calorific value are reduced and stabilized to an appropriate level so as to match the temperatures of the sample 112 with the target values.

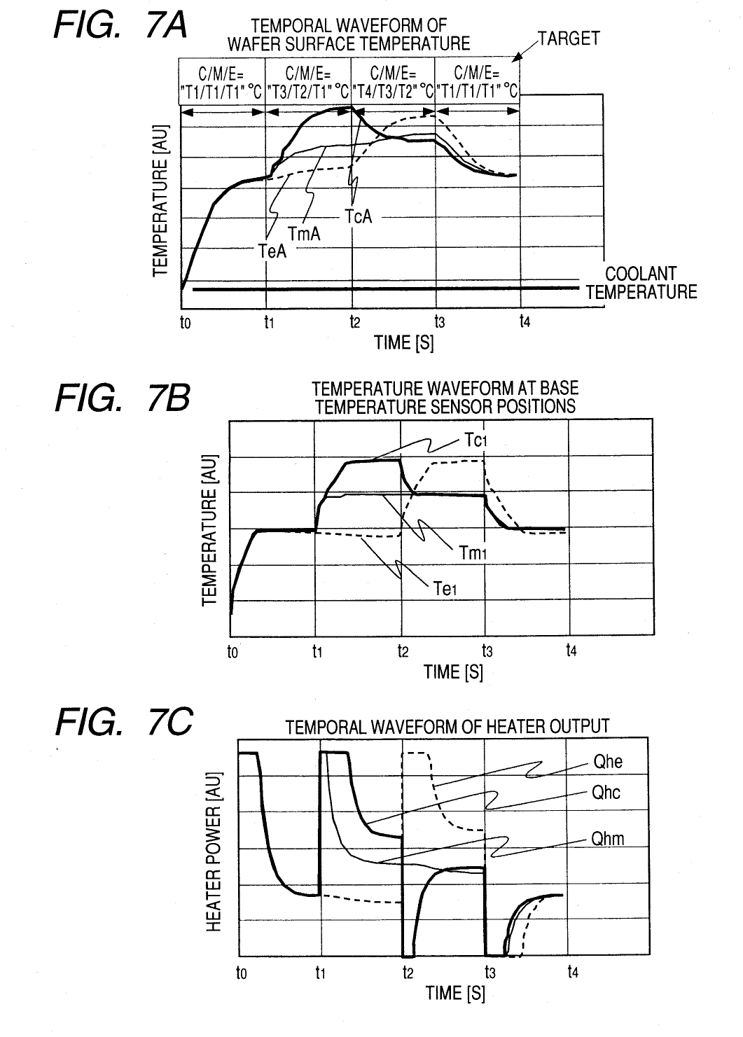

As a comparative example, FIGS. 7A to 7C show time-lapse changes in the temperature T_{A} (c, m, e) of the sample 112 in a plasma etching apparatus 100 without the temperature estimating unit 127 for estimating the temperature of the sample 112. In this example, which corresponds to a related art example, signals outputted by the temperature monitors 126 shown in FIG. 4 are transmitted to the control computing unit 128, bypassing the wafer temperature estimating unit 127.

From FIG. 7A, it is understood that the temperatures T_{A} (c, m, e) of the sample 112 are shifted from the target values by 5° C. to 8° C. over the time period shown in the graph and that the convergence of the temperatures T_{A} to the target values are inadequate and each temperatures T_{A} is not stabilized. FIG. 7B is a graph showing time-lapse changes in the temperatures of the sample 112 or sample stage 113 detected from signals based on outputs from the temperature monitors 126 of the base 112. While the temperatures of the base member 121 are controlled so as to match the target values also in this example, the graph representing the temperatures T1 (c, m, e) of the base member 121 takes a sharp shape. FIG. 7C is a graph showing time-lapse changes in power Qh (c, m, e) from the heater power supply 115. Also from this graph, it is understood that the changes in the magnitude of power are moderate, the convergence is lost, and the outputs are not stabilized compared to the changes based on the temperature control according to this embodiment shown in FIG. 6C.

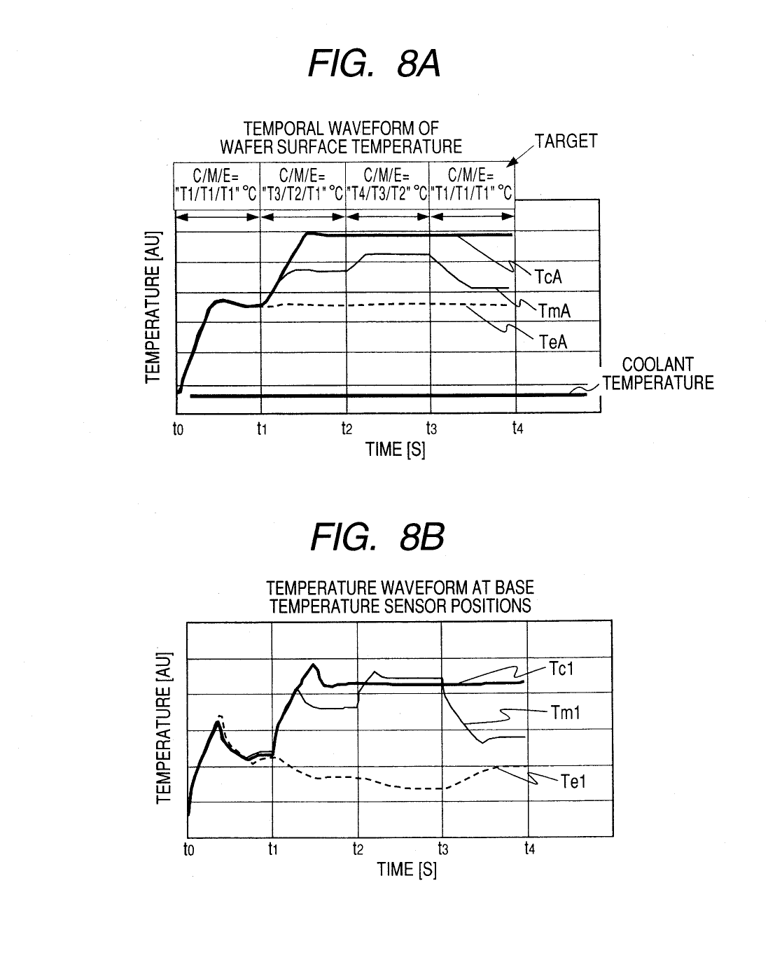

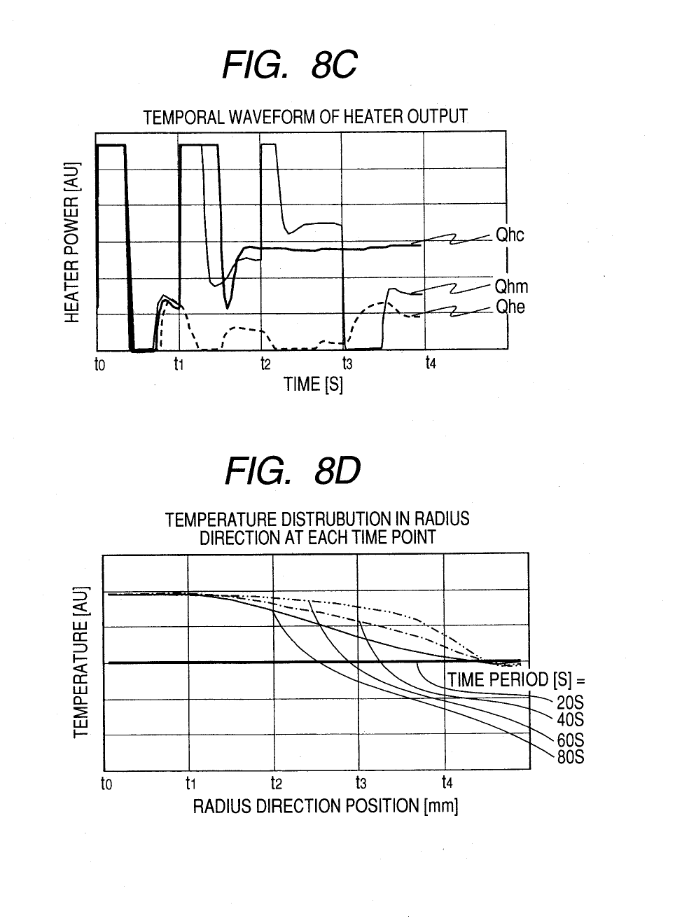

FIGS. 8A to 8D are graphs showing the temperature control of the middle part of the sample 112 and its effect according to this embodiment.

In general, when poly-Si or SiO₂ is etched, a good etching result can often be obtained if the temperature of the surface of the sample 112 or sample stage 113 shows a so-called convex distribution in which the temperature is high in the central part of the sample 112 or sample stage 113 and relatively low in its edge part. However, the optimum shape of the convex distribution by which the desired result can be achieved varies depending on the type of film or processing conditions. Related art examples have a problem in that the etched shape of the surface of the sample 112 is not sufficiently uniform because while the difference in temperature between the central and edge parts can be changed, the profile (shape of the temperature graph) of the temperature distribution cannot be changed.

In this embodiment, the electrode 124 films are disposed in the adjacent three parts of the surface of the sample stage 113 including the central, middle, and edge parts. The operation (heating, output) of each electrode films 124 is independently controlled. Therefore, the temperature profile described above can be fine-tuned.

The temperature and time conditions in FIGS. 8A to 8D are the same as those in FIGS. 6A to 6C. In FIG. 8A, the temperatures T (c, m, e) of the sample 112 estimated using formula 4 and the actual temperatures T_{A} (c, m, e) are overlapped. FIG. 8B is a graph showing time-lapse changes in the temperatures T1 (c, m, e) detected based on outputs from the temperature monitors 126 of the base member 121. FIG. 8C shows time-lapse changes in output of power Qh (c, m, e) from the heater power supply. From FIG. 8D, it is understood that changing the target value for the middle part allows the temperature of the middle part to be changed, allowing the profile to be fine-tuned.

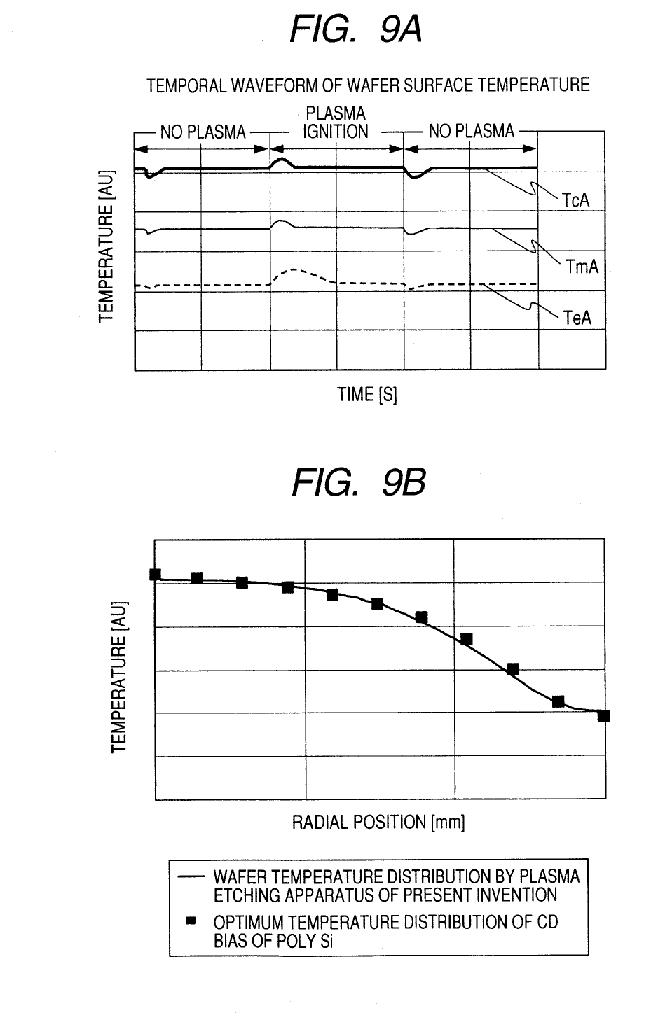

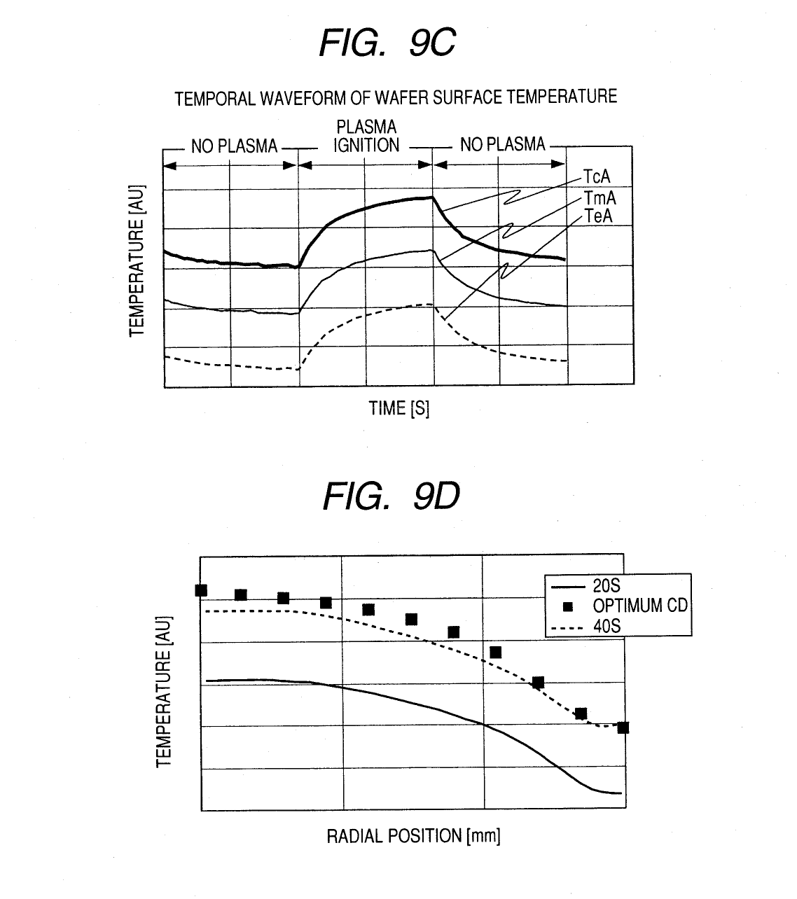

FIGS. 9A to 9D are intended to compare the aspect of restraint of temperature changes after plasma ignition according to this embodiment with that according to a related art example. The temperature and time conditions in FIGS. 9A to 9D are the same as those in FIGS. 6A to 6C. FIGS. 9A and 9B are graphs showing the temperatures of the sample 112 according to this embodiment, and FIGS. 9C and 9D are graphs showing the temperatures of the sample 112 according to the related art example.

In the related art example, when the sample 112 is carried onto the sample stage 113, etching is started upon plasma ignition, and a disturbance occurs due to heat input from plasma, the characteristics shown in FIGS. 9C and 9D are demonstrated, resulting in increases in the temperature of the sample 112. Depending on the conditions, the etching performance may be deteriorated because the temperatures of the sample 112 are not constant at the initial stage of etching. It is understood that in the related art example, the temperatures rise by about 10° C., taking about t1 sec. after plasma ignition and thus are not stable.

According to this embodiment, as shown in FIGS. 9A and 9B, the temperature changes at the initial stage are small and are restrained, for example, within about 1.5° C. This makes it possible to carry out stable, high performance etching.

Among various causes that make the temperature of the sample 112 unstable include time-lapse changes in the temperature of the coolant and increases in the temperature of the sample 112 due to radiant heat caused by increases in the temperature of the members inside the etching processing chamber 111. According to this embodiment, the detection results of the temperatures of the sample 112 or sample stage 113 are fed back so that the temperatures of the sample 112 are controlled. Therefore, even if these disturbances occur, the temperatures of the sample 112 can be maintained stably.

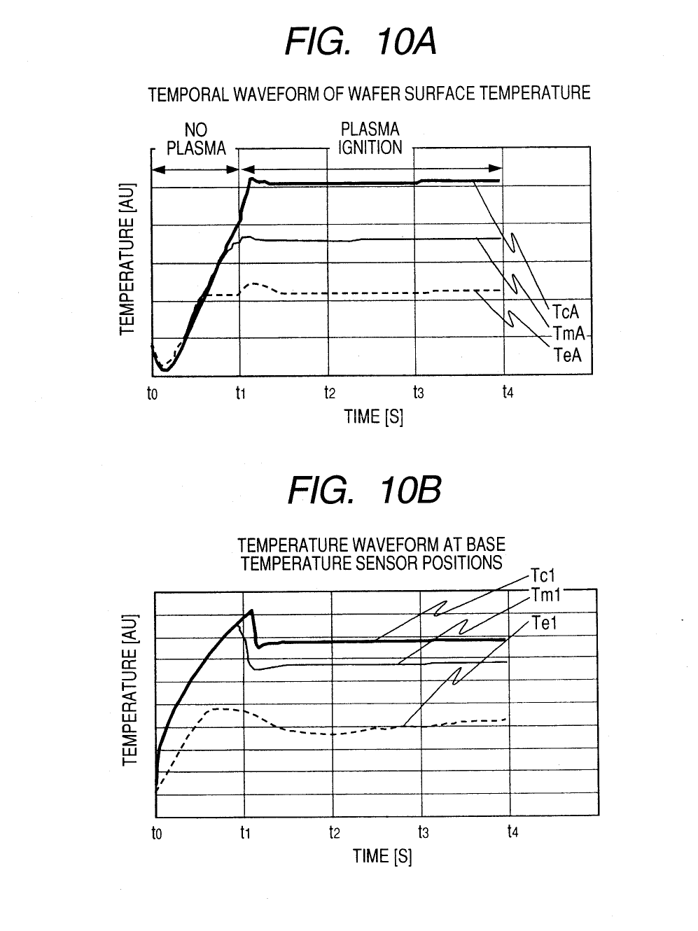

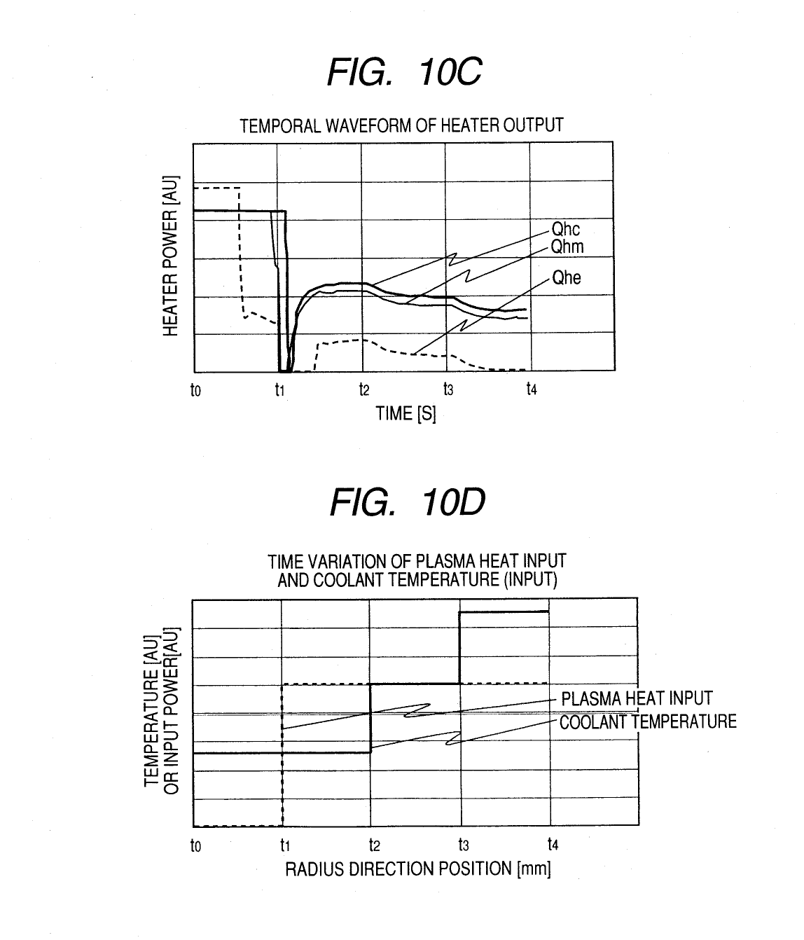

FIGS. 10A to 10D are graphs showing an example of changes in the temperature of the sample 112 according to this embodiment when increases in heat input from plasma and increases in the temperature of the coolant occur as the abovementioned disturbances. Specifically, FIGS. 10A to 10D show time-lapse changes in the temperature of the sample 112 when the temperature of the coolant increases stepwise, for example, by 5° C. and then 10° C. after plasma ignition and at the same time heat input from plasma also increases stepwise.

FIG. 10D is a graph showing time-lapse changes in the temperature of the coolant and changes in the magnitude of heat input from plasma. FIG. 10A is a graph showing the T_{A} (c, m, e) of the central, middle, and edge parts of the sample when these disturbances occurs. FIG. 10B is a graph showing temperatures T1 (c, m, e) detected based on outputs from the temperature monitors 126 of the base member 121. FIG. 10C is a graph showing time-lapse changes in the output from the heater power supply.

From these graphs, it is understood that even if the temperature of the coolant rises with increases in heat input from plasma, changes in the temperature of the parts of the sample 112 are restrained and thus the temperatures of those parts are controlled stably, compared with the related art example.

This invention is applicable not only to the plasma etching apparatus described above but also to plasma processing apparatuses in general, including plasma CVD apparatuses suitable for performing ion implantation or sputtering.

What is claimed is:

1. A plasma processing apparatus comprising:
a processing chamber to be depressurized and exhausted;
a sample stage provided in the processing chamber and having a sample placement surface on which a substrate to be processed is placed;
a plasma generating device for generating plasma in the processing chamber;
a heat transfer gas supply system for supplying heat transfer gas to the sample placement surface; and
a coolant channel portion provided inside the sample stage and through which a coolant circulates; wherein the apparatus further comprises:
a heater layer provided between the sample placement surface and the coolant channel portion inside the sample stage, wherein the heater layer is formed so as to be divided into a plurality of regions in a radius direction of the sample placement surface;
a plurality of temperature monitors provided near the heater layer in the sample stage and in a position corresponding to each of the division regions of the heater layer; and
a temperature controller for estimating a temperature of a position corresponding to each of the division regions of the substrate placed on the sample placement surface base on temperature data from the plurality of temperature monitors and controls power supply to each of the division regions of the heater layer according to the estimated temperature value.

2. The plasma processing apparatus according to claim 1,
wherein the heater layer is divided into plural regions so as to correspond to each of regions obtained by dividing the substrate placed on the sample placement surface into plural regions where area is equal in a radius direction, and
the temperature controller has a function of estimating a temperature of a position corresponding to each of the division regions of the substrate based on heat balance of the substrate per se and heat balance of the sample stage.

3. The plasma processing apparatus according to claim 2,
wherein the temperature controller has a wafer temperature estimating unit that estimates a temperature of a position corresponding to each of the division regions of the substrate by a first order lag computation using temperatures detected by the temperature monitors, input power to each of the division regions of the heater layer, and heat input from the plasma to the substrate as inputs.

4. The plasma processing apparatus according to claim 2,
wherein the temperature controller has:
a function for controlling a temperature of the coolant circulating inside the sample stage so that the temperature of the coolant is a value lower than a minimum of a control target temperature value of the substrate; and
a function for obtaining heat balance of heat that enters and leaves each of the division regions of the heater layer based on temperature data from the temperature monitors and estimating a temperature of a position of the substrate to be processed corresponding to each of the division regions.

5. The plasma processing apparatus according to claim 2,
wherein the temperature controller has a feedback control unit controls input power to each of the division regions of the heater layer based on a difference between the estimated temperature and target temperature.

6. The plasma processing apparatus according to claim 5,
wherein the temperature controller performs any one of an on/off control computation and a proportional-integral control computation on a signal representing a difference between the target value and the estimated value of the substrate in order to generate an instruction value of input power to the heater layer.

7. The plasma processing apparatus according to claim 3,
wherein the apparatus further comprises:
a high frequency bias power supply that applies bias high frequency power to the sample stage,
wherein the wafer temperature estimating unit performs a first order lag computation on a linear combination signal of the signal using input power to the heater layer, electromagnetic field input power to the plasma, the bias high frequency power, and signals from the temperature monitors as inputs, and thereby outputs an estimated temperature value of the substrate.

8. A plasma processing apparatus comprising:
a processing chamber to be depressurized and exhausted;
a processing gas supply system for supplying processing gas to the processing chamber;
a sample stage provided in the processing chamber and having a sample placement surface on which a substrate to be processed is placed, the sample stage including:
a base member;
a heater layer provided above the base member, being formed so as to be divided into a plurality of regions in a radius direction of the sample placement surface; and
a dielectric material film covering the heater layer and including the sample placement surface,
a bias power supply for applying bias power to the sample stage;
an electromagnetic generation device for generating plasma in the processing chamber;
a heat transfer gas supply system for supplying heat transfer gas to the sample placement surface; and
a coolant channel portion provided inside the sample stage and through which a coolant circulates; wherein the apparatus further comprises:
a plurality of base temperature monitors provided near a surface of the base member for measuring a temperature of a position corresponding to each of the division regions of the heater layer; and
a temperature controller for estimating a temperature of a position corresponding to each of the division regions of the substrate placed on the sample placement surface base on temperature data from the base temperature monitors using electromagnetic field input power to the plasma and the bias power as inputs and controls power supply to each of the division regions of the heater layer according to the estimated temperature value of the substrate.

9. The plasma processing apparatus according to claim 8,
wherein the heater layer is disposed so as to correspond to the approximately entire sample placement surface and divided so as to have approximately equal areas in a radius direction.

10. The plasma processing apparatus according to claim 9,
wherein each of the division regions formed by dividing the heater layer in the radius direction is divided into a plurality of blocks in a circumferential direction, and the plurality of division blocks are connected in series.
